(19) United States
(12) Patent Application Publication
(10) Pub. No.: US 2006/0102319 A1
(43) Pub. Date: May 18, 2006

(54) Heat dissipation enhancing device

(75) Inventor: Wen-Hao Liu, Taipei (TW)

Correspondence Address: G. LINK CO., LTD.;Suite 137, PmB 174, 931 West 75th Street, Naperville, IL, 60565, US

(73) Assignee: ASIA VITAL COMPONENT CO., LTD.

(21) Appl. No.: 10/988,518

(22) Filed: Nov. 16, 2004

(51) Int. Cl. H05K 7/20

(52) U.S. Cl. 165/80.3; 165/109.1; 361/697

(57) ABSTRACT

A heat dissipation enhancing device includes a cooling fan and a radiator. The radiator is attached with the cooling fan and has cooling fins with flow passages being formed between the cooling fins for fluid driven by the cooling fan passing through the flow passages performing heat exchange heat in the radiator. At least a turbulent component is formed in the flow passages respectively. The heat convection of the fluid in the flow passages can be promoted and heat dissipation efficiencies of the cooling fins can be enhanced effectively.

### BACKGROUND OF THE INVENTION

1. Field of the Invention

The present invention is related to cooing fins with heat dissipation enhancing device and particularly to a turbulent element being disposed between the cooling fins of a radiator respectively to remove heat from heat generation component effectively.

2. Brief Description of the Related Art

There are two significant approaches for development of electronic products. One is that electronic products being made with lightness, thinness, shortness and smallness. The other one is that the electronic products being made with high performance and multi-functions. Due to parts in the electronic products generating much more heat and having smaller sizes, heat flux becomes increasing rapidly such that performance and reliability of the respective electronic product are affected so as even to shorten life spans thereof if heat dissipation is unable to be promoted effectively.

For CPU in a desktop computer, a heat dissipation module of aluminum/copper radiator associated with cooling fan is essential. The radiator occurs heat conduction phenomenon and the cooling fan occurs heat convection such that a purpose of heat exchange can be reached and the heat dissipation module can perform effective heat removal. In order to overcome increased heat from heat generated parts, the current used heat dissipation module is not satisfied with heat dissipation need except increasing rotational speed of the cooling fan for producing more flow rate and enhancing effect of forced convection. However, increasing rotational speed of the cooling fan not only is restricted due to size thereof being limited and the motor providing limited driving force but also produces much noise. Hence, it is required that developing radiator to comply with future challenge and solving problems resulting from promoted performances of various electronic products.

Referring to FIGS. 1 and 1A, the conventional heat dissipation device includes a radiator 11 and a cooling fan 12 joined to the radiator 11. The radiator 11 is fixedly attached to a heat generation part 13. The radiator 11 has a base 111 with a plurality of cooling fins 112 and flow passages 113 are formed between the cooling fins 112. The cooling fan 12 has a fan frame 121 and the fan frame 121 further has an inlet 122 and an outlet 123 with a plurality of fan blades 124 movably disposed therein. When the fan blades 124 rotate, cold air can be driven to flow toward the radiator 11 at the outlet 123 from the inlet 122. The air passes through the flow passages and flows outward to carry heat transmitted to the cooling fins 112 from the heat generation part 13 so as to reduce temperature.

The preceding way for removing heat has a problem to high heat electronic products in operation. It can be seen in FIG. 1 that the radiator 11 closely touches the heat generation part 13 and the cooling fan is joined to the top of the radiator 11. It is clearly that heat transfer is processed from a stationary substance and heat transfer occurs by way of moving from high temperature to low temperature. The heat is transmitted along with convection and is removed during the heat moving farther from the heat generation substance, that is, area nearer the heat generation part 13 provides higher heat. Hence, the base 111 and root sections of the cooling fins 112 provide highest temperature and the cooling fins 112 at the tops thereof provide reduced temperature. The velocity gradient of fluid created from the cooling fan 12 decreases gradually along with longer distance so that flow rate at the outlet 123 is larger and the flow rate at the end of the flow passages is smallest. Referring to FIG. 1A, because root sections of the cooling fins 112 provides high temperature and the top sections thereof has low temperature, the temperature gradient from the root sections to the top sections is decreasing. When cold fluid driven by the cooling fan 12 reaches ends of the flow passages 113, heat boundary layer at root sections of the flow passages 113 is thicker and it is getting thinner upward along the flow passages 113 and effect of heat convection is reduced so that it is very limited that the cold fluid carries the heat to the ambient environment and the heat dissipation function of the heat dissipation device is incapable of being performed well so as to lead reduced running life of the heat generation part 13. 122 can form a airflow stagnation zone under the hub 121 and it results in the airflow being unable to move smoothly. Thus, the overall effect of heat dissipation of the cooling fan is influenced significantly.

### SUMMARY OF THE INVENTION

An object of the present invention is to provide a heat dissipation enhancing device, which has a turbulent component being disposed in the flow passages between cooling fins respectively, to enhance heat convection at the flow passages and heat dissipation efficiency of the radiator.

Another object of the present invention is to provide a heat dissipation enhancing device, which has a turbulent component made of good heat conductive material and being disposed in the flow passages between cooling fins respectively, to enhance heat convection at the flow passages and heat dissipation efficiency of the radiator.

### BRIEF DESCRIPTION OF THE DRAWINGS

The detail structure, the applied principle, the function and the effectiveness of the present invention can be more fully understood with reference to the following description and accompanying drawings, in which:

FIG. 1 is a sectional view of a conventional heat dissipation device;

FIG. 1A is an enlarged view of area A shown in FIG. 1;

FIG. 2 is a disassembled sectional view of the first embodiment of cooling fins with heat dissipation enhancing device according to the present invention;

FIG. 3 is an assembled sectional view of the first embodiment of cooling fins with heat dissipation enhancing device according to the present invention;

FIG. 4 is a sectional view illustrating the first embodiment of cooling fins with heat dissipation enhancing device according to the present invention being closely touched to a heat generation component;

FIG. 5 is disassembled sectional view of the second embodiment of cooling fins with heat dissipation enhancing device according to the present invention;

FIG. 6 is an assembled sectional view of the second embodiment of cooling fins with heat dissipation enhancing device according to the present invention;

FIG. 7 is an assembled sectional view of the third embodiment of cooling fins with heat dissipation enhancing device according to the present invention;

FIG. 8 is another assembled sectional view of the third embodiment of cooling fins with heat dissipation enhancing device according to the present invention; and

FIG. 9 is a sectional view illustrating another type turbulent component being attached to the respective flow passages in the heat dissipation enhancing device.

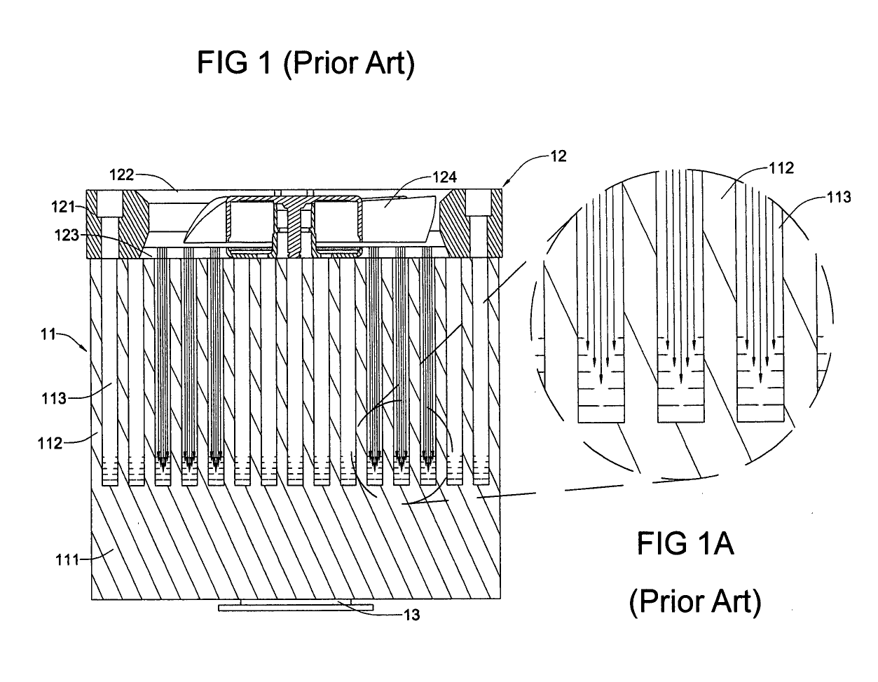

### DETAILED DESCRIPTION OF THE INVENTION

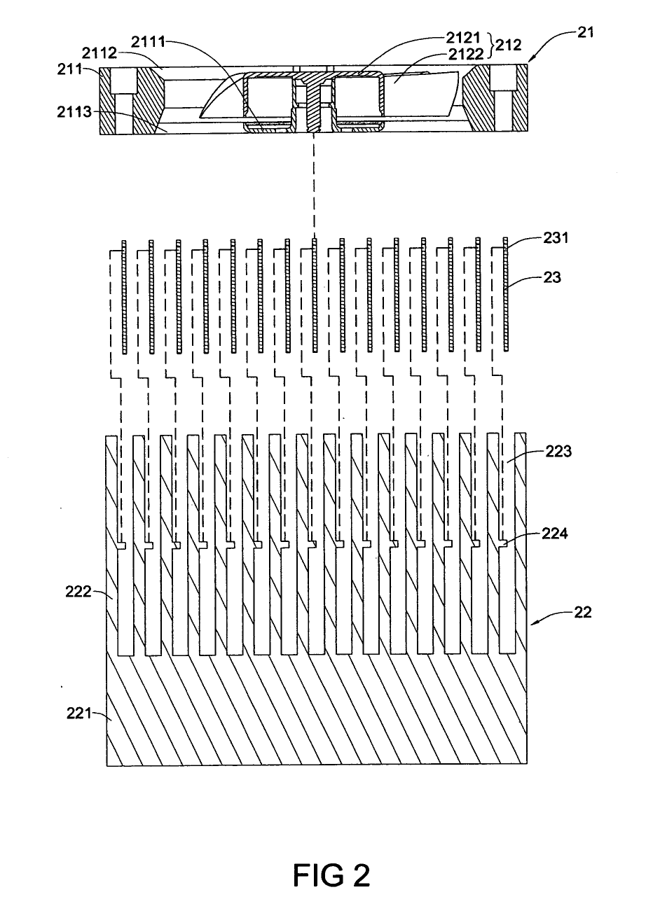

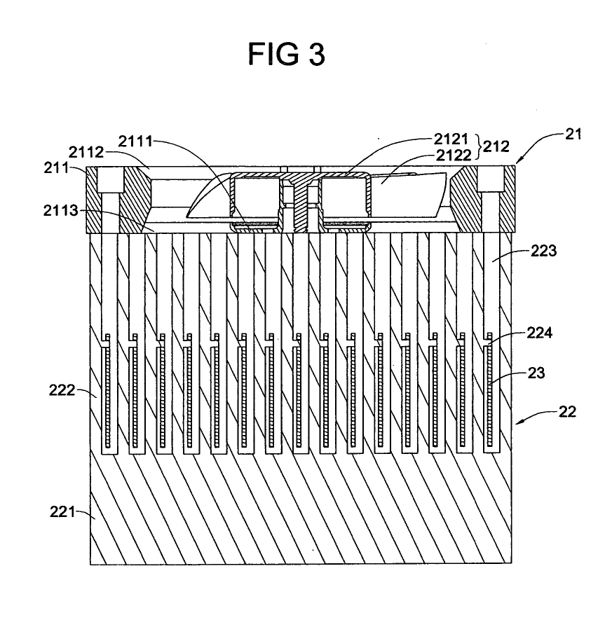

Referring to FIGS. 2 and 3, the first embodiment of cooling fins with heat dissipation enhancing device according to the present invention comprises a cooling fan 21 and a radiator 22. The cooling fan 21 has a fan frame 211 with a hub seat 2111 formed in the fan frame 211 and an inlet 2112 and an outlet oppositely formed at the periphery of the fan frame 211. The hub seat 2111 movably connects with a fan wheel 212 and the fan wheel 212 further comprises a hub 2121 and a plurality of fan blades 2122 extending outward from the circumstance of the hub 2121. The radiator 22 has a base 221 with a plurality of cooling fins 222 formed on the base 221 in a way of a flow passage 223 formed between the cooling fins 222. Each of the cooling fins 222 provides a joining part 224 jutting out from the wall thereof and at least a turbulent component 23 made of good heat conduction material is attached to the respective cooling fin 222 with a receiving part 231 being attached to the joining part 224 such that the turbulent component 23 is disposed in the respective flow passage 223. Further, the cooling fan 21 is attached to the top of the radiator 22.

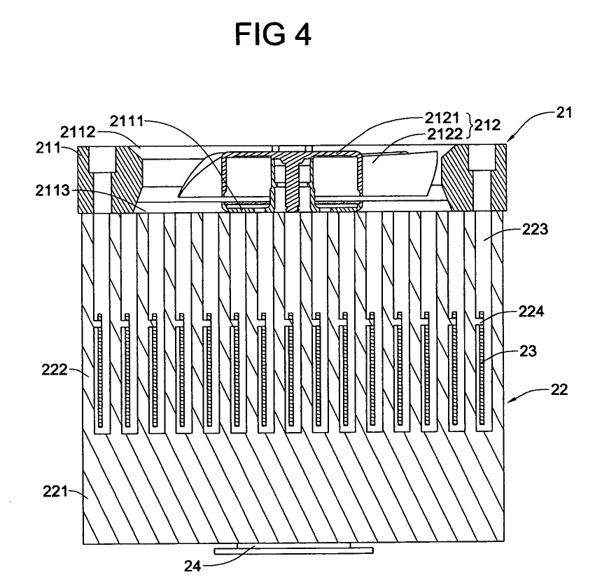

Referring to FIG. 4, the radiator 22 is fixedly joined to a heat generation component 24 such that heat from the heat generation component 24 can transmit to the top of each of the cooling fins 222 via the base 221 of the radiator 22. When the fan wheel 212 rotates, the fan blades 2122 drive fluid to pass through the inlet 2112 and flow toward the radiator 22 at the outlet 2113. Then, the fluid can move outward via the flow passages 223. When the fluid passes through the flow passages 223, the fluid makes the turbulent component 23 being in a passive state and a thicker heat boundary layer at the bottom of the respective flow passage 23 is broken by way of actuation of the turbulent component 23. In this way, cold fluid at the top of the respective flow passage 23 can carry a great deal of heat to increase convection efficiency and promote effect of the heat dissipation.

Due to the turbulent component 23 being made of good heat conduction material with any suitable shape and being provided on the wall of the respective cooling fin 222, it can enhance heat convection function of the radiator 22 so that high heat dissipation efficiency of the radiator 22 can be reached effectively.

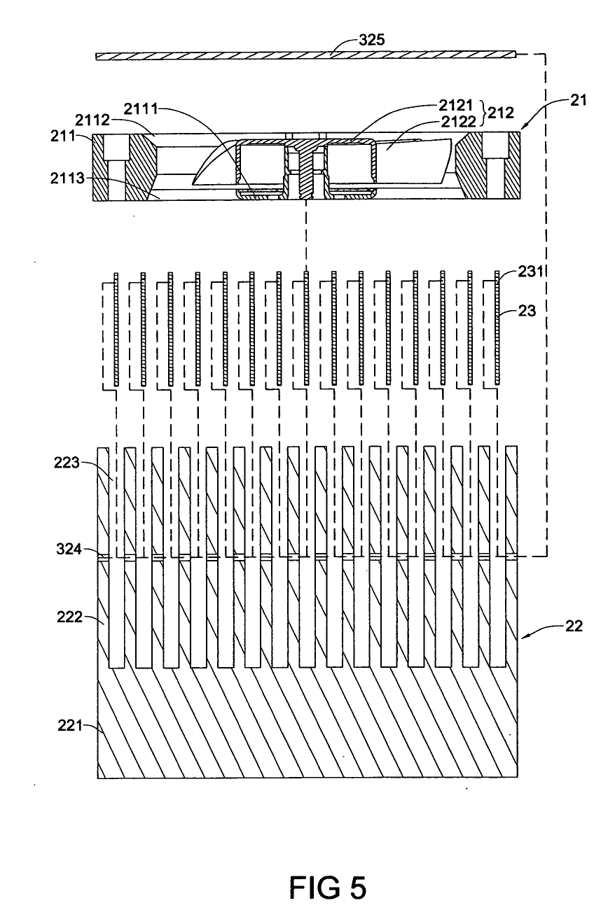

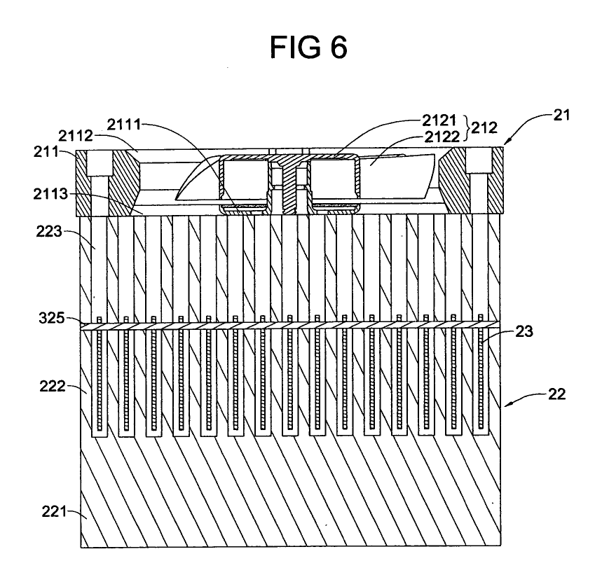

Referring to FIGS. 5 and 6, the second embodiment of the present invention is illustrated. The entire structure and function are very similar to the first embodiment and the same parts and reference numbers will not be explained again. The difference of the present embodiment is in that each of the cooling fins 222 is provided with a through hole 324 and a connecting rod 325 is provided to pass through the through hole 324 and the receiving part 231 of the turbulent component 23 respectively such that the turbulent component 23 can be movably disposed at the respective flow passage 223 to promote heat convection of the fluid in the passages 223 and heat dissipation efficiency of the cooling fins 222.

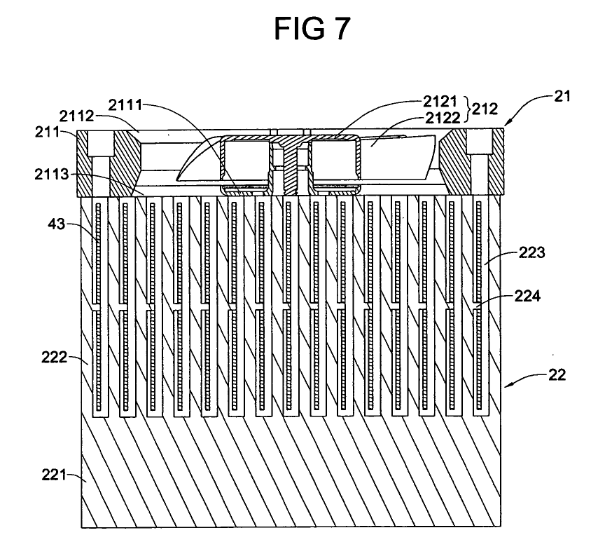

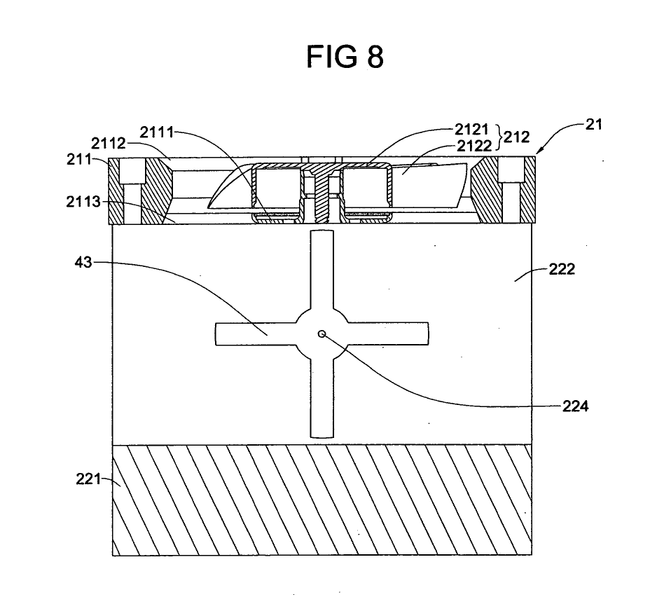

Referring to FIGS. 7 and 8, the third embodiment of the present invention is illustrated. The entire structure and function are very similar to the receding embodiment and the same parts and reference numbers will not be explained again. The difference of the present embodiment is in that the turbulent component 43 is provided with a shape of sector. When the fan wheel 212 rotates, the fluid actuates the turbulent component 43 joined in the respective flow passages to rotate and flow speed of the fluid gets faster by means of the turbulent component 43 such that the thicker heat boundary layer at the bottom of each of the flow passages 223 can be thinned to enhance heat convection efficiency and heat dissipation efficiency of the radiator.

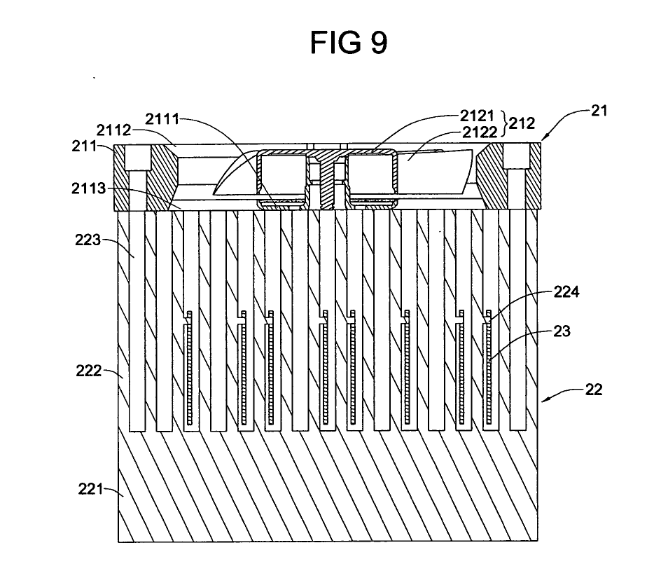

Further, the turbulent components 23, 43 in the preceding embodiments can be movably joined in any flow passages 223 as shown in FIG. 9 instead of being arranged in each of the flow passages 223. Alternatively, a driving part can be joined to the turbulent components 23, 43 respectively such that the turbulent components can be driven individually (not shown) and the heat convection efficiency can be enhanced and the dissipation function can be promoted as well.

While the invention has been described with referencing to preferred embodiments thereof, it is to be understood that modifications or variations may be easily made without departing from the spirit of this invention, which is defined by the appended claims.

What is claimed is:

1. A heat dissipation enhancing device, comprising:
a cooling fan; and
a radiator, being attached with the cooling fan, having a plurality of cooling fins with a plurality of flow passages being formed between the cooling fins for being passed through with fluid driven by the cooling fan so as to perform heat exchange between the fluid and heat in the radiator;
characterized in that at least a turbulent component is formed in the flow passages respectively;
whereby, the heat convection of the fluid in the flow passages can be promoted and heat dissipation efficiencies of the cooling fins can be enhanced effectively.

2. The heat dissipation enhancing device as defined in claim 1, wherein the turbulent component is moved by the fluid driven by the cooling fan.

3. The heat dissipation enhancing device as defined in claim 1, wherein the turbulent component is provided with a driving component so that the turbulent component can move by itself.

4. The heat dissipation enhancing device as defined in claim 1, wherein the turbulent component is disposed in the flow passages respectively.

5. The heat dissipation enhancing device as defined in claim 1, wherein the turbulent component is disposed in the flow passages optionally.

6. The heat dissipation enhancing device as defined in claim 1, wherein each of the cooling fins is formed with a projection for being joined with the turbulent component respectively.

7. The heat dissipation enhancing device as defined in claim 1, wherein the turbulent component is made of a material with good heat conductivity.
